(19) United States
(12) Patent Application Publication
(10) Pub. No.: US 2009/0052556 A1
(43) Pub. Date: Feb. 26, 2009

(54) FREQUENCY INTERLEAVING METHOD FOR WIDEBAND SIGNAL GENERATION

(76) Inventor: Andrew D. Fernandez, Sunnyvale, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/844,254

(22) Filed: Aug. 23, 2007

(51) Int. Cl. H04B 1/66; H03M 1/66

(52) U.S. Cl. 375/241; 341/144; 375/240

(57) ABSTRACT

Wideband signal generation systems and methods are provided which employ frequency interleaving for generating wideband signals. A general method increases a digitally synthesized signal's bandwidth by frequency interleaving multiple digitally synthesized signal sources of narrower bandwidth. Frequency interleaving creates a continuous wideband signal by summing multiple narrower band signals that overlap in frequency. According to certain embodiments, digital signal processing (DSP) and analog mixing are used to create the multiple narrower band signals such that a high fidelity, continuous wideband signal is produced when the multiple narrower band signals are summed.

### TECHNICAL FIELD

The following description relates generally to wideband sign generation, and more specifically to systems and methods for using frequency interleaving for wideband signal generation.

### BACKGROUND OF THE INVENTION

Current communications systems exhibit a trend toward higher transmit and receive signal bandwidths. Such bandwidths afford greater data rates (as in WiMAX, discussed below) or allow the communication to appear as background noise that does not interfere with pre-existing wireless systems (as in UWB, discussed below). These bandwidth requirements often exceed the capabilities of state of the art signal generation and digitization solutions. Not surprisingly, test and measurement instruments follow the same trend toward generating and digitizing increasingly wider bandwidth signals, often with the additional requirement of improved dynamic range over that of commercial systems.

WiMAX (Worldwide Interoperability for Microwave Access) is a telecommunications technology aimed at providing wireless data over long distances in a variety of ways, from point-to-point links to full mobile cellular type access. WiMAX is based on the IEEE 802.16 standard, which is also called WirelessMAN. WiMAX allows a user to, for example, browse the Internet on a laptop computer without physically connecting the laptop to a wall jack.

Ultra-Wideband (UWB) is a technology for transmitting information spread over a large bandwidth (>500 MHz) that should, in theory and under the right circumstances, be able to share spectrum with other users. The FCC has authorized the unlicensed use of USE in 3.1-10.6 GHz, which is intended to provide an efficient use of scarce radio bandwidth while enabling both high data rate personal-area network (PAN) wireless connectivity and longer-range, low data rate applications, as well as radar and imaging systems. High data rate UWB can enable wireless monitors, the efficient transfer of data from digital camcorders, wireless printing of digital pictures from a camera without the need for an intervening personal computer, and the transfer of files among cell phone handsets and other handheld devices like personal digital audio and video players, as examples.

A desire often arises for generating a wideband digital signal. In state of the art signal generators, signal bandwidth is limited by the digital-to-analog converter (DAC) sample rate, I/Q modulator bandwidth, and the bandwidth of other analog components in the signal path. Typically, the sample rate of the DAC is the primary limitation to the generated signal bandwidth. For example, FIG. 1 shows a block diagram of a prior art signal generating system 10 that is commonly employed for generating radio frequency (RF) signals 17. System 10 comprises an in-phase (I) DAC 11 and a quadrature (Q) DAC 12 for I and Q channels, respectively. To attempt to generate wideband signals, a DAC having as wide a band as possible may be implemented. So, a system such as that of FIG. 1 typically uses an I DAC 11 and a Q DAC 12, which are clocked at the maximum sample rate possible. Each channel may be fed through reconstruction filters 13, 14, which remove higher order spectral images of the converted signal. Typically, these images are unwanted and “distort” the desired DAC output Each channel is then modulated by an IQ modulator 15, wherein the outputs of the I and Q channel are summed by summation circuit 16 to generate an upconverted wideband signal output 17 centered at frequency f_{LO} (where “LO” refers to local oscillator). That is, IQ modulator 15 receives the I and Q channels and modulates the I and Q channels by sinusoids 90 degrees out of phase. Modulation with orthogonal carriers in this manner is spectrally efficient and is prevalent in communications systems today.

Standard notation for complex baseband and passband signals is as follows. The baseband signal is designated x_{c}(t) and is referred to as the complex envelope. A passband signal is designated x_{z}(t) and is the upconverted baseband signal.

x_{z}(t)=x₁(t)+jx_{Q}(t), where x₁(t) and x_{Q}(t) are real signals.

x_{c}(t)=\sqrt{2}·Re[x_{z}(t)·e^{j2πf}^{ₑ}¹]

x_{c}(t)=\sqrt{2}·[x₁(t)cos(2πf_{c}t)−x_{Q}(t)sin(2πf_{c}t)]

DAC sample rate is the primary factor that limits signal generator bandwidth in the technique employed by the exemplary system 10 of FIG. 1. The well-known Nyquist criterion specifies that the bandwidth of the converted analog signal can be no greater than one half (½) the DAC sample rate. Thus, when two DACs 11, 12 feed an I/Q modulator 15 (as in the case of FIG. 1), the upconverted output 17 has a signal bandwidth of no greater than twice (2×) that of each of the input paths. Thus, the exemplary signal generation technique of FIG. 1 is limited to R signal synthesis of signals 17 that have a bandwidth no greater than 2× the bandwidth of I DAC 11 or Q DAC 12.

Additionally, as shown in the example of FIGS. 2A and 2B, summing the output of multiple signal generators is a common technique to create multi-carrier wireless signals. For instance, multiple signal generators, such as the exemplary signal generator 10 described with FIG. 1, may be employed in a signal generation system 20 of FIG. 2A, which shows such signal generators 10A, 10B, 10C, 10D, and 10E that generate RE signals 17A, 17B, 17C, 17D, and 17E, respectively. Such signals 17A-17E are summed by summing circuit 21 to generate a multi-carrier wireless signal 22. However, as illustrated in FIG. 2B, such a multi-carrier wireless signal 22 is not truly wideband, as it contains “holes” in the spectrum, and the sub-carriers do not necessarily share a fixed magnitude and phase relationship. For instance, as shown in FIG. 2B, the generated signal 22 contains the plurality of summed signals 17A-17E with holes 23A, 23B, 23C, and 23D interspersed between. Thus, the exemplary summing technique of FIGS. 2A-2B does not allow wideband signal generation that is free of in-band spectral discontinuities. Frequencies that lie within spectral holes 23A, 23B, 23C, and 23D cannot be synthesized with the aforementioned technique.

While the multi-carrier technique of FIGS. 2A-2B can generate signals 22 with energy at many places in a given bandwidth, these signals have frequency “holes” (e.g., holes 23A-23D). These holes exist by design so that the information content at one carrier frequency does not interfere with adjacent carriers. This approach to subdividing a larger band into sub-bands works well for a given multi-channel communication format. However, this approach is inflexible and impractical for general-purpose wideband, such as is desired for “software radio” signal generation. In the communications area, the general-purpose transceiver is often referred to as a “software radio”. Other signals, such as high fidelity wideband radar chirps, are impossible to re-create using the exemplary multi-carrier technique described above.

Thus, a desire exists for an improved system and method for generating wideband signals.

### BRIEF SUMMARY OF THE INVENTION

The present invention is directed to systems and methods which employ frequency interleaving for generating wideband signals. According to embodiments of the present invention, a general method is provided to increase a digitally synthesized signal's bandwidth by frequency interleaving multiple (i.e., at least 2) digitally synthesized signal sources of narrower bandwidth. Frequency interleaving creates a continuous wideband signal (i.e., one without holes, such as holes 23A-23D in the exemplary multi-carrier signal 22 of FIG. 2B) by summing multiple narrower band signals that overlap in frequency. According to certain embodiments, digital signal processing (DSP) and analog mixing are used to create the multiple narrower band signals such that a high fidelity, continuous wideband signal is produced when the multiple narrower band signals are summed.

According to one embodiment, signal generation techniques are employed to generate multiple narrower bandwidth signals. For instance, a plurality of signal generators, such as the exemplary signal generator of FIG. 1, may be employed to each generate a signal. Thus, each of the multiple signals may be generated with the maximum bandwidth possible (e.g., using the state of the art techniques). This embodiment of the present invention then employs frequency interleaving of the multiple signals to generate a wideband signal. Nat is, the signal generation system interleaves the multiple signals, each with a frequency offset, such that the signals overlap in the frequency domain.

Thus, according to this embodiment, the multiple signals are each generated with the same signal generation technique (e.g., the exemplary signal generation technique of FIG. 1), and such signals are then frequency interleaved. Thus, the exemplary signal generation system of this embodiment is not limited by the sample rate of the available DACs that might be employed for generating each of the multiple signals.

Normally, summing frequency overlapped bands would be thought by those of ordinary skill in the art to be disastrous, since each signal channel would overlap with the adjacent channel and cause interference. However, by careful system design, it is possible to sum frequency overlapped bands, compensate for any interference, and generate the desired wideband signal. One way to mitigate this interference problem is to filter each band to remove unwanted spectral leakage. According to certain embodiments of the present invention, the burden of filtering the signals is split between analog and digital domains to allow channels to be combined and overlapped.

Analog filters are often used to remove unwanted spectral components (these filters include the reconstruction filters that typically follow DACs, as well as RF filters that remove unwanted components following mixing). In addition, analog filters may be used to “shape” the response of the generated signal such that signals within the passband are not attenuated and signals within the stopband are attenuated. Often, digital filtering used in conjunction with analog filters improves the desired filter response and compensates for imperfections typical of analog filters. These imperfections include non-linear phase, unflatness in the passband, slow roll of, and insufficient stopband attenuation.

According to one embodiment, the following actions may be performed in the analog domain:

a) two or more signals are synthesized using separate signal generation circuits;

b) these signals may be upconverted (using a device known as a mixer) to the desired center frequency;

c) the signals are filtered to remove unwanted spectral components;

d) a frequency reference is distributed between signal generation circuits to ensure a fixed frequency and phase relationship; and

e) a calibration procedure determines the frequency response of each signal generation circuit, as well as the phase offset (and possibly frequency offset, if it is not precisely known).

According to one embodiment, the following actions may be performed in the digital domain:

a) the input digital representation of the desired wideband signal is filtered to separate the desired aggregate wideband signal to multiple narrower band component signals;

b) each component signal is filtered to compensate for imperfections in the signal generation circuit (for example, sine rolloff in the DAC);

c) each component signal is digitally rotated to compensate for the upconverter (or I/Q modulator) frequency and phase mismatch between the multiple signal generation circuits;

d) each component signal is filtered to compensate for I/Q modulator imperfections; and

e) each component signal is filtered to compensate for frequency response mismatch between the multiple signal generation circuits.

The order of operations identified above is intended as only an example. In addition, multiple cascaded digital filters may be folded into a single filter for a more compact implementation according to an embodiment of the present invention. In addition it may be desirable to apply nonlinear transformations in the digital domain to compensate for nonlinear imperfections of any analog component used for signal generation or upconversion.

According to certain embodiments of the present invention, the multiple, narrower band signals are each generated via a respective generation path, and the paths are tied together such that each one knows about the other. So, for example, when a baseband signal is frequency translated to an intermediate or R frequency signal there is a local oscillator that is employed, wherein such local oscillator has a frequency and a phase. So, in the multiple generation paths, if the relative frequencies and phases are locked together (i.e., they may be “locked together” in this manner by reference to a common local oscillator that is used for setting their respective frequencies and phases), the multiple signals will not drift in frequency or phase relative to each other.

Further, according to certain embodiments of the present invention, the signal generation system accounts for the fact that oftentimes, in practice, there are delays in each signal generation path. For instance, there may exist gain imbalances or magnitude response differences between the multiple, narrower band generation paths. The signal generation system of certain embodiments removes those differences between the signal generation paths using DSP before the signal generation portion such that after the signals go through the various impairments in each path, the output is identical at each site. The output is referred to as being “identical” in this regard in that each of the multiple, narrower band signals maintain relative frequencies and phases that are locked together, and not that the output signals are duplicates of each other. The digital signal processing (DSP) is intended to equalize the magnitude, phase, I/Q imbalances, nonlinearities, and other mismatches between paths. So, the outputs from the multiple signal generation paths can be summed together to produce a high fidelity, continuous wideband signal.

Thus, the wideband signal generation systems and methods of certain embodiments of the present invention enable signals to be generated with a bandwidth greater than that possible with traditional, state of the art signal generation techniques. Additionally, the frequency interleaving method employed by certain embodiments of the present invention generates continuous wideband signals, thus avoiding “spectral holes” that appear in certain multi-cattier signal generation techniques, such as those discussed with FIGS. 2A-2B above.

Additionally, for improved signal fidelity (improved interleaving image suppression), a digital approach to frequency interleaving is employed in certain embodiments of the present invention, which digitally matches channels with more accuracy than is achievable with traditional approaches. While similar filtering techniques may be employed in certain prior art systems, they have not been employed in the context of frequency interleaving.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawing, in which:

FIG. 1 shows an exemplary prior art system for generating signals, wherein the bandwidth of the generated signal is limited to no greater than twice the bandwidth of a digital-to-analog converter (DAC) employed in the system;

FIGS. 2A-2B show another exemplary prior art system for generating signals, which sums the output of multiple signal generators to create multi-carrier wireless signals that contain “holes” in the spectrum;

FIG. 3 shows an exemplary graph illustrating frequency overlapped bands in which each signal channel overlaps with the adjacent channel;

FIG. 4 shows an exemplary block diagram of a wideband signal generator according to one embodiment of the present invention;

FIG. 5 shows an exemplary operational flow diagram of a wideband signal generator according to an embodiment of the present invention;

FIG. 6 shows a graph illustrating multiple sources stitched together in the frequency domain to result in a continuous wideband signal that comprises multiple adjacent channels with no spectral “holes” therebetween according to one embodiment of the present invention;

FIG. 7 shows an exemplary signal generation architecture that may be employed according to embodiments of the present invention, wherein the signal generator uses I/Q modulation for frequency interleaved RF signal generation;

FIG. 8 shows another exemplary signal generation architecture that may be employed according to embodiments of the present invention, wherein the signal generator provides frequency interleaved RE signal generation with heterodyne upconversion;

FIG. 9 shows another exemplary signal generation architecture that may be employed according to embodiments of the present invention, wherein the signal generator provides frequency interleaved RE signal generation using multiple DACs operating in different Nyquist bands; and

FIG. 10 shows an exemplary block diagram of the digital signal processing (DSP) flow that may be implemented within a wideband signal generator of embodiments of the present invention for providing digital filtering (frequency response equalization), I/Q mismatch correction, local oscillator frequency and phase mismatch correction, and nonlinear corrections.

### DETAILED DESCRIPTION OF THE INVENTION

Frequency interleaving, according to embodiments of the present invention, creates a continuous wideband signal by summing multiple narrower band signals which overlap in frequency. According to certain embodiments, the frequency interleaving technique uses digital signal processing (DSP) and analog mixing to create these narrower band signals such that they create a high fidelity, continuous wideband signal when summed.

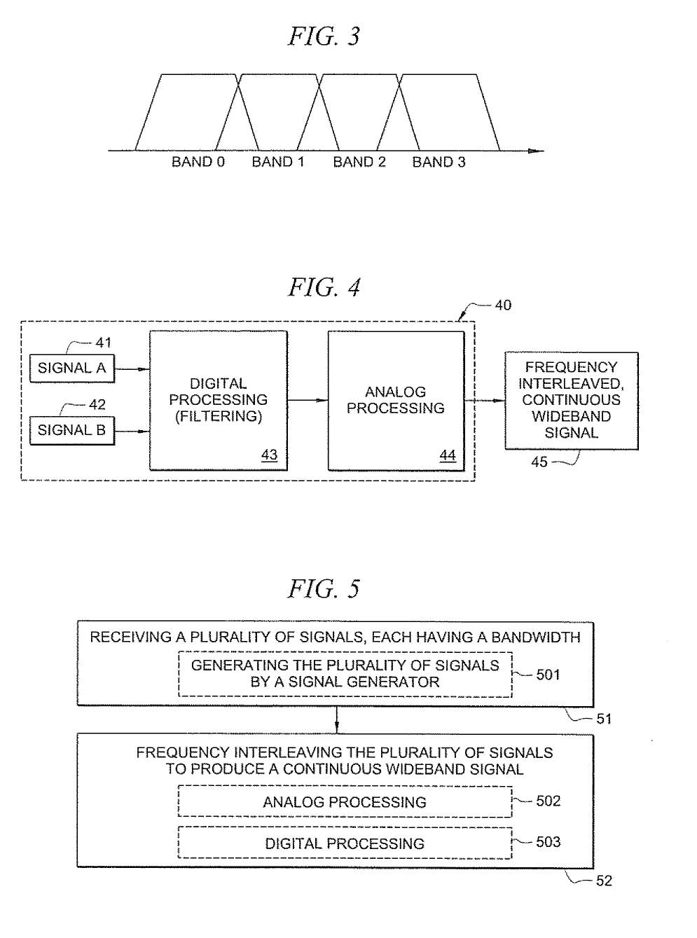

As the example of FIG. 3 shows, information content from multiple bands may be combined to create a continuous wideband signal with arbitrary spectral content. Practically, there will be some redundant information in each generated signal. The overlap eliminates the redundant information. According to certain embodiments of the present invention, a filtering operation equalizes the magnitude and phase variation between the summed paths. The filtering operation also allocates frequency content to each signal generator.

Normally, summing frequency overlapped bands would be considered disastrous by those of ordinary skill in the art, since each signal channel would overlap with the adjacent channel and cause interference, such as illustrated in FIG. 3. One way to avoid this problem is to filter the signal. A perfect filter with no transition band (“brick wall”) is needed to place frequency content from one DAC immediately adjacent to that of another without interference. Unfortunately, such analog filters are impossible to achieve in practice.

Embodiments of the present invention thus split the burden between the analog and digital domains to allow channels to be combined and overlapped. According to one embodiment, the signal is partitioned between multiple upconversion channels, the channels' frequency responses are matched, and the upconverters' local oscillator phases are matched using digital filtering. The outputs of the DACs are upconverted and optionally filtered using standard analog techniques. In certain embodiments, a digital block of the system may perform absolute calibration (calibrating the output signal to a known level and phase) as well.

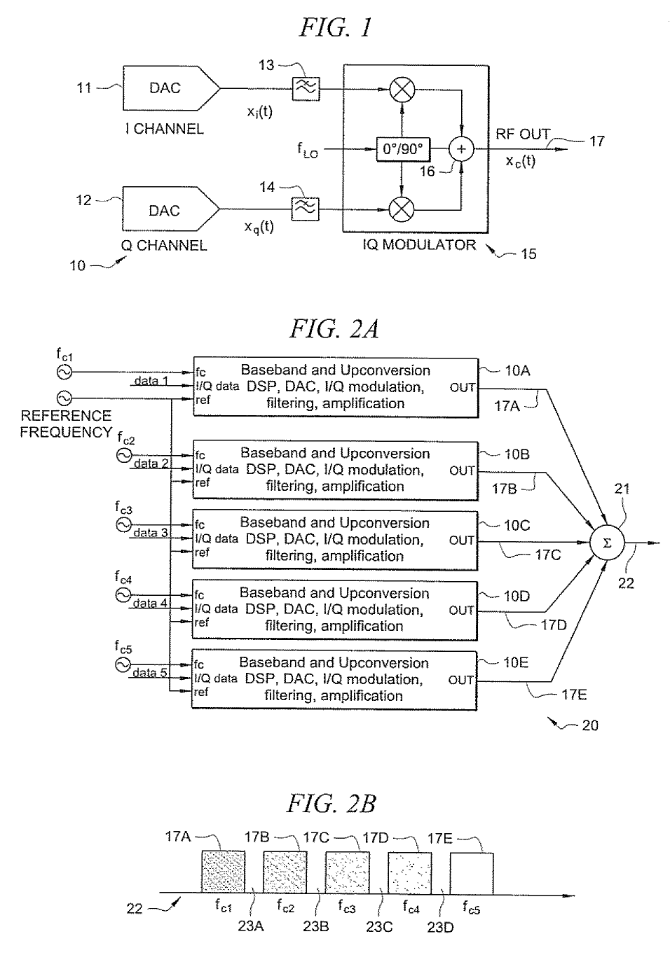

Turning to FIG. 4, an exemplary block diagram of a wideband signal generator 40 according to an embodiment of the present invention is shown. As shown, wideband signal generator 40 comprises digital processing block 43 and analog processing block 44. A plurality of narrower bandwidth signals, such as signals 41 and 42, are processed by the digital processing block 43 and analog processing block 44 to perform frequency interleaving of the multiple signals 41, 42 to generate a wideband signal 45. As discussed further herein, the generated wideband signal 45 is referred to as being “continuous” because it does not have “holes” in between the signals contained therein, such as the holes 23A-23D shown in FIG. 2B.

According to certain embodiments, signal generation techniques are employed to generate the multiple narrower bandwidth signals 41, 42 within signal generator 40. For instance, a plurality of signal generators, such as the exemplary signal generator of FIG. 1, may be employed to each generate one of the signals 41 and 42. Thus, each of the multiple signals may be generated with the maximum bandwidth possible (e.g., using the state of the art techniques). The signal generator 40 then employs frequency interleaving of the multiple signals 41, 42 to generate a wideband signal 45. That is, the signal generator 40 interleaves the multiple signals 41, 42 with the signals being offset in frequency such that the signals overlap in the frequency domain. Accordingly, the exemplary signal generator 40 of this embodiment is not limited by the sample rate of the available DACs that might be employed for generating each of the multiple signals 41, 42.

As discussed above, typically signal generators generate arbitrary waveforms with a bandwidth of W₁, where W₁ is less than Fs/2 in a single DAC system, where Fs is the sample rate. A signal generator with an I/Q modulator may generate signals with a bandwidth of W₂, where W₂ is less than twice Fs/2 (in other words, W₂ is less than Fs). This is because the bandwidth of two DACs is combined using the I/Q modulator, such as in the exemplary system of FIG. 1.

However, according to an embodiment of the present invention, a frequency interleaving method is employed by a signal generator (such as signal generator 40 of FIG. 4) which uses M DACs to generate a wideband signal having a bandwidth of W₃. The bandwidth W₃ is less than M*Fs/2, but since the number, M, of DACs employed in the signal generator can potentially be greater than 2, wider band signals can be created than is achievable with previous state of the art signal generators. For instance, according to certain embodiments, at least 3 DACs are employed.

As mentioned above, summing frequency overlapped bands would normally be thought by those of ordinary skill in the art to be disastrous, since each signal channel would overlap with the adjacent channel and cause interference. However, by careful system design, it is possible to sum frequency overlapped bands, compensate for any interference, and generate the desired wideband signal. One way to mitigate this interference problem is for signal generator 40 to filter each band to remove unwanted spectral leakage. According to certain embodiments of the present invention, the burden of filtering the signals is split between analog domain 44 and digital domain 43 to allow channels to be combined and overlapped.

Analog filters are often used to remove unwanted spectral components (these filters include the reconstruction filters that typically follow DACs, as well as R filters that remove unwanted components following mixing). In addition, analog filters may be used to “shape” the response of the generated signal such that signals within the passband are not attenuated and signals within the stopband are attenuated. Often, digital filtering used in conjunction with analog filters improves the desired filter response and compensates for imperfections typical of analog filters. These imperfections include non-linear phase, unflatness in the passband, slow roll off, and insufficient stopband attenuation.

In this exemplary embodiment, various operations may be performed in the digital processing block 43 and analog processing block 44. For instance, in digital processing block 43, such operations as filtering (FIR or IIR), phase rotation, frequency translation, and optionally nonlinear corrections may be performed, while in analog processing block 44 such operations as digital to analog conversion, image rejection filtering, mixing, upconversion, I/Q nodulation, amplification, and any further filtering may be performed.

FIG. 5 shows an exemplary operational flow diagram of a wideband signal generator of one embodiment of the present invention. In operational block 51, the wideband signal generator receives a plurality of signals, each having a bandwidth. For instance, as shown in FIG. 4, signals 41 and 42 may be received. In certain embodiments, as indicated by sub-operational block 501, the signal generator generates such signals, thereby receiving them as a result of its generation of them. Each of the signals 41 and 42 have a narrower bandwidth than the wideband signal 45 that is generated by the wideband signal generator 40.

In operational block 52, the wideband signal generator 40 performs frequency interleaving of the plurality of signals 41, 42 to produce a continuous wideband signal 45. As shown in sub-operational blocks 502 and 503, digital and analog processing of the plurality of signals may be performed to produce a high fidelity, continuous wideband signal 45. As described above with FIG. 4, various operations may be performed in the digital processing block 43 and analog processing block 44. For instance, in digital processing block 43, such operations as filtering (FIR or IIR), phase rotation, frequency translation, and optionally nonlinear corrections may be performed, while in analog processing block 44 such operations as digital to analog conversion, image rejection filtering, mixing, upconversion, I/Q modulation, amplification, and any further filtering may be performed.

According to one embodiment, in the analog processing sub-operational block 502, wideband signal generator 40 may perform the following exemplary operations (by analog processing block 44 of FIG. 4):

a) two or more signals are synthesized using separate signal generation circuits;

b) these signals may be upconverted (using a device known as a mixer) to the desired center frequency;

c) the signals are filtered to remove unwanted spectral components;

d) a frequency reference is distributed between signal generation circuits to ensure a fixed frequency and phase relationship; and

e) a calibration procedure determines the frequency response of each signal generation circuit, as well as the phase offset (and possibly frequency offset, if it is not precisely known).

According to one embodiment, in the digital processing sub-operational block 503, wideband signal generator 40 may perform the following exemplary operations (by digital processing block 4) of FIG. 4):

a) the input digital representation of the desired wideband signal is filtered to separate the desired aggregate wideband signal to multiple narrower band component signals;

b) each component signal is filtered to compensate for imperfections in the signal generation circuit (for example, sine rolloff in the DAC);

c) each component signal is digitally rotated to compensate for the upconverter (or I/Q modulator) frequency and phase mismatch between the multiple signal generation circuits;

d) each component signal is filtered to compensate for I/Q modulator imperfections;

e) each component signal is filtered to compensate for frequency response mismatch between the multiple signal generation circuits; and

f) optionally, apply nonlinear transformations in the digital domain to compensate for nonlinear imperfections of any analog component used for signal generation or upconversion.

The order of operations described above for the analog and processing sub-blocks 502-503 is intended as only an example only. In addition multiple cascaded digital filters may be folded into a single filter in certain embodiments for a more compact implementation.

According to one embodiment, each channel comprises one or more DACs and an upconversion circuit. For instance, in one exemplary implementation of the signal generation system, each channel comprises an I and Q DAC, followed by reconstruction filters, followed by an I/Q modulator. Thus, each channel may be implemented as system 10 of FIG. 1 discussed above, where each channel comprises I DAC 11, Q DAC 12, reconstructions filters 13 and 14, and I/Q modulator 15 for producing a signal 17. Alternately, in certain embodiments each channel may have a single DAC, followed by a reconstruction filter, then followed by a mixer with an optional filter.

Alternately, in certain embodiments each channel may have a DAC and a reconstruction filter. In this case, the DAC mode provides the frequency translation by operating in the 1st, 2nd, 3rd, . . . , Nyquist zones. Note that the 2^{nd}, 3^{rd}, etc. Nyquist zones describe a DAC that can provide significant frequency content at a multiple of the Nyquist rate (Fs/2). For example, a DAC with energy in 2^{nd} Nyquist is able to generate frequency content between Fs/2 and Fs, where Fs is the sample rate. Each module is driven by one DSP block which provides the following functions: channelization, channel matching and the necessary calibration. The DSP block may contain FIR, IIR, and frequency translation components.

The outputs of each channel are summed using well-known techniques. One commonly used summation circuit is a resistive power combiner. Note that even the resistive combiner will not be perfectly balanced, or have a flat frequency response. Hence, calibration across the various paths (through each channel of the system, and through the power combiner itself) is preferably employed to allow N channels, each with a bandwidth of M, to operate as a single channel with a bandwidth approaching N*M.

According to one embodiment of the signal generator, the DAC sample clocks and mixer LOs are phase locked and low jitter to create a high signal-to-noise ratio (SNR) signal. The phase of the LOs is thus preferably known and stable Calibration may utilize a pilot tone on each of the parallel signal paths to extract the LO phase relative to the sample clock.

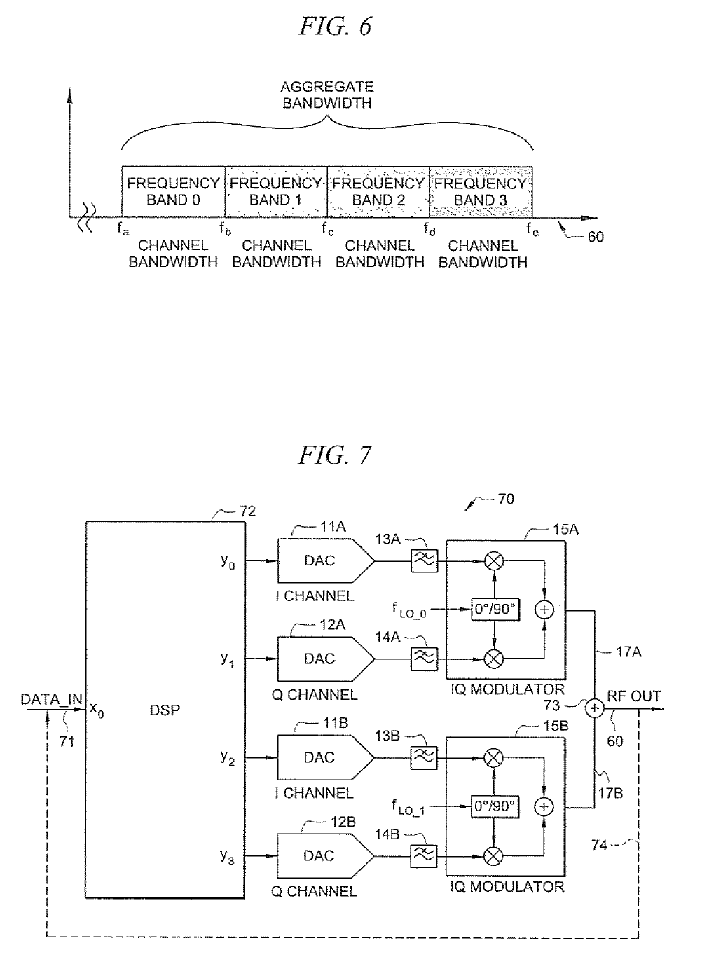

According to embodiments of the present invention, two or more baseband signals (usually generated with DACs) are frequency interleaved. FIGS. 6-9 discussed hereafter illustrate an exemplary technique employing 4 frequency interleaved DACs using a variety of frequency translation techniques. While 4 frequency interleaved DACs are employed for illustrative purposes in these techniques, it should be recognized that the concepts described herein are not limited to 4 such frequency interleavings, but may likewise be extended to any number of frequency interleavings that may be desired. FIG. 6 illustrates a concept of “stitching together” multiple sources in the frequency domain. As can be seen, FIG. 6 illustrates an exemplary continuous wideband signal 60 that comprises multiple adjacent channels with no spectral “holes” therebetween. As such, the aggregate bandwidth is a continuous wideband comprising a plurality of narrower band signals that are frequency interleaved.

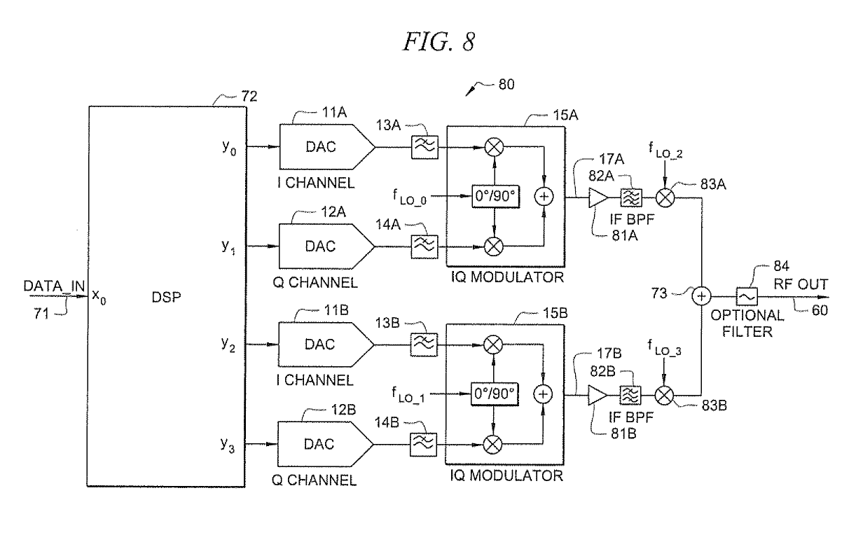

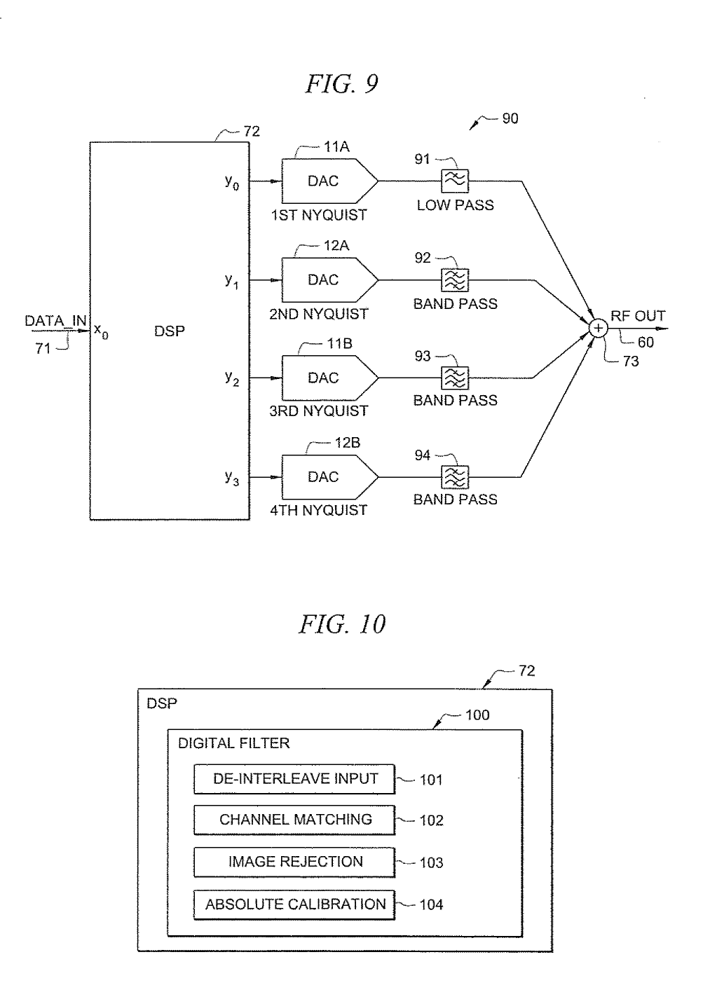

FIGS. 7-9 show exemplary block diagrams of different signal generation architectures that may be utilized for employing the frequency interleaving concept for generating continuous wideband signals, such as signal 60 of FIG. 6. These exemplary architectures include I/Q modulator upconversion (FIG. 7), heterodyne/homodyne upconversion (FIG. 8), and interleaving DACs operating in different Nyquist zones (FIG. 9).

Although not explicitly shown, it should be evident that all clocks and local oscillators are phase locked in the exemplary signal generation systems now described with FIGS. 7-9. This ensures that the frequency relationship (and consequent sampling relationship) between channels remains fixed. In addition, the digital signal processing (DSP) block in the exemplary architectures of FIGS. 7-9 allows each channel to be more perfectly matched. This step is not essential to the method of frequency interleaving. However, it improves signal fidelity by reducing unwanted interference from adjacent channels. For some applications, the signal created by frequency interleaving may be unusable (low fidelity) without DSP-assisted channel matching.

FIG. 7 shows one exemplary signal generation architecture that may be employed according to embodiments of the present invention. The exemplary signal generator 70 of FIG. 7 uses I/Q modulation for frequency interleaved W signal generation. In this example, signal generator 70 comprises two channels, where each channel comprises two DACs and an upconversion circuit. For instance, in this example, each channel comprises an I and Q DAC, followed by reconstruction filters, followed by an I/Q modulator. For instance, the first channel of signal generator 70 comprises I DAC 11A, Q DAC 12A, reconstruction filters 13A and 14A, and I/Q modulator 15A; while a second channel of signal generator 70 comprises I DAC 11B, Q DAC 12B, reconstruction filters 13B and 14B, and I/Q modulator 15B. Signal generator 70 further comprises a DSP 72, and summation logic (e.g., a resistive power combiner) 73. As discussed further hereafter, signal generator 70 is operable to produce a continuous wideband signal 60, such as that of FIG. 6 discussed above.

In operation, DSP 71 receives a Data_In signal 71. Digital signal processing (DSP) block 71 may be implemented using digital signal processors that are known in the art (such as those available from Texas Instruments or Analog Devices), reconfigurable logic devices known as field-programmable gate arrays (FPGAs), or custom logic known as application specific integrated circuits (ASICs), as examples. Each implementation platform has its strengths and weaknesses. The choice of one platform depends on such factors as performance, power, budget.

The Data_In signal 71 in this example refers to the digital representation of the desired wideband signal at the output. The DSP 72 block in this example refers to all subsequent processing of that signal in the digital domain before conversion to analog form. The processing includes in this exemplary embodiment:

a) the input digital representation of the desired wideband signal is filtered to separate the desired aggregate wideband signal to multiple narrower band component signals;

b) each component signal is filtered to compensate for imperfections in the signal generation circuit (for example, sinc rolloff in the DAC);

c) each component signal is digitally rotated to compensate for the upconverter (or I/Q modulator) frequency and phase mismatch between the multiple signal generation circuits;

d) each component signal is filtered to compensate for I/Q modulator imperfections;

e) each component signal is filtered to compensate for frequency response mismatch between the multiple signal generation circuits; and

f) optionally, apply nonlinear transformations in the digital domain to compensate for nonlinear imperfections of any analog component used for signal generation or upconversion.

Again, the order of operations described above for DSP block 72 is intended as an example only. In addition, multiple cascaded digital filters may be folded into a single filter in certain embodiments for a more compact implementation.

DSP 72 outputs the 4 separate signals (via the outputs y₀, y₁, y₂, and y₃ shown in the example of FIG. 7). The outputs from y₀ and y₁ are received by I DAC 11A and Q DAC 12A, and are processed through such DACs 11A and 12A, reconstruction filters 13A and 14A, and I/Q modulator 15A in the traditional manner as discussed above with the example of FIG. 1 to produce signal 17A. Similarly, the outputs from y₂ and y₃ of DSP 72 are received by I DAC 11B and Q DAC 12B, and are processed through such DACs 11B and 12B, reconstruction filters 13B and 143, and I/Q modulator 15B in the traditional manner as discussed above with the example of FIG. 1 to produce signal 17B.

Signals 17A and 17B are then summed by summation circuit 73 to produce the continuous, frequency interleaved wideband signal 60. In certain embodiments, a calibration path 74 may be provided from the output 60 to the input 71 in order to perform calibration for determining the mismatch between each path (11A and 12A, 11B and 12B, and so on, up to 17A and 17B).

FIG. 8 shows another exemplary signal generation architecture that may be employed according to embodiments of the present invention. The exemplary signal generator 80 of FIG. 8 provides frequency interleaved M signal generation with heterodyne upconversion. As with the example of FIG. 7 discussed above, signal generator 80 comprises two channels, where each channel comprises two DACs and an upconversion circuit. For instance, in this example, each channel comprises an I and Q DAC, followed by reconstruction filters, followed by an IQ modulator. For instance, the first channel of signal generator 80 comprises I DAC 11A, Q DAC 12A, reconstruction filters 13A and 14A, and I/Q modulator 15A; while a second channel of signal generator 80 comprises I DAC 11B, Q DAC 12B, reconstruction filters 13B and 14B, and I/Q modulator 15B. Also like signal generator 70 of FIG. 7 discussed above, signal generator 80 further comprises a DSP 72, and summation logic (e.g., a resistive power combiner) 73.

In operation, DSP 71 receives a Data_In signal 71. DSP 71 processes the received signal as discussed above with FIG. 7. Further, the outputs of each channel from the DSP 71 are processed by DACs 11A, 12A, 18, 12B, reconstruction filters 13A, 14A, 13B, 14B, and I/Q modulators 15A and 15B to produce signals 17A and 17B in the manner discussed above with FIG. 7.

In this exemplary embodiment, f_{LO}_{_{—}}₀=f_{LO}_{_{—}}₁. That is, the center frequency for I/Q modulator 15A and I/Q modulator 15B are identical. In this case, respective signals 17A and 17B are at the same center frequency. Amplifiers 81A and 81B amplify the signal and intermediate frequency (IF) bandpass filter 82A and 82B remove any unwanted spurs and images that are a byproduct of the I/Q modulator. Mixer 83A and 83B mix the signals from intermediate frequency f_{LO} to the final RF frequency. With appropriate choice of t_{LO}_{_{—}}₂ and f_{LO}_{_{—}}₃, these two signals overlap in the frequency domain. They are summed with summing circuit 73. Again, any unwanted spectral images or spurs generated by the mixing process are filtered out using optional bandpass filter 84. The need for this filter depends on the mixer chosen as well as the application requirements.

In an implementation in which f_{LO}_{_{—}}₀ does not equal f_{LO}_{_{—}}₁, then the exemplary embodiment of FIG. 8 can be simplified by choosing these initial carrier frequencies for I/Q modulator 15A and I/Q modulator 15B such that their output signals appropriately overlap with each other in frequency. This is identical to the exemplary embodiment of FIG. 7. Then, summing circuit 73 would follow directly after IF bandpass filter 82A and 82B. A mixer (such as mixer 83A or 83B) would then be placed following the summing circuit 73 to allow the wideband signal to be translated to a higher frequency. Again, any unwanted spectral images or spurs generated by the mixing process are filtered out using optional bandpass filter 84. This second scenario is simply frequency translation of FIG. 7 described above.

FIG. 9 shows another exemplary signal generation architecture that may be employed according to embodiments of the present invention. The exemplary signal generator 90 of FIG. 9 provides frequency interleaved RF signal generation using multiple DACs operating in different Nyquist bands. As with the example of FIG. 7 discussed above, signal generator 90 comprises two channels, where each channel comprises two DACs. For instance, in this example, each channel comprises an I and Q DAC. For instance, the first channel of signal generator 90 comprises I DAC 11A and Q DAC 12A; while a second channel of signal generator 90 comprises I DAC 11B and Q DAC 12B. Also like signal generator 70 of FIG. 7 discussed above, signal generator 90 further comprises a DSP 72, and summation logic (e.g., a resistive power combiner) 73.

In operation, DSP 71 receives a Data_In signal 71. DSP 71 processes the received signal as discussed above with FIG. 7. Further, the outputs of each channel from the DSP 71 are processed by DACs 11A, 12A, 11B, 12B. In this example, DACs 11A, 12A, 11B, and 12B are operating in different Nyquist bands. For instance, DAC 11A is operating in a first Nyquist zone, DAC 12A is operating in a second Nyquist zone, DAC 11B is operating in a third Nyquist zone, and DAC 12B is operating in a fourth Nyquist zone. Therefore, FIG. 9 illustrates an example of interleaving multiple DACs operating in the 1st, 2nd, 3rd, and 4^{th} Nyquist zones. Note, it is possible for a DAC to generate significant spectral energy centered on a frequency other than between DC and Fs/2. Various commercially available DACs operate in multiple Nyquist zones, such as the MAX19692 DAC.

This is typically referred to as the 1st Nyquist zone. As an example, if a doublet generating circuit at the DAC output is used instead of the typical zero order hold, significant energy is placed in the 2nd Nyquist zone. This output pulse shape modulates the DAC output with a signal at 2× the sample rate, upconverting the output signal to be centered at Fs. For practical considerations, it may be desirable in certain embodiments to modify the sampling frequencies of the component DACs such that their outputs overlap in the frequency domain.

The analog filters 91-94 included in the exemplary embodiment of FIG. 9 are used to remove extraneous spectral images in the multi-Nyquist DACs before their outputs are summed. For example, the lowpass filter 91 attenuates all images above Fs/2 (above the 1^{st} Nyquist zone). The band-pass filter 92 attenuates all images not between Fs/2 and Fs (the 2^{nd} Nyquist zone). The band-pass filter 93 attenuates all images not between Fs and 3*Fs/2 (the 3^{rd} Nyquist zone). The band-pass filter 94 attenuates all images not between 3*Fs/2 and 2*Fs (the 4^{th} Nyquist zone). In certain embodiments, frequency interleaving may be performed without the use of these filters. With appropriate choice of the phase of the DAC sample clock, these filters may become redundant. Thus, such an analogous frequency interleaving approach may be implemented without employing filters 91-94, but use of the analog filters 91-94 may simplify the digital filters applied in block 72.

As discussed above, DSP 72 may implement a digital filter. An exemplary block diagram of such a DSP 72 according to one embodiment is shown in FIG. 10. As shown, DSP 72 may be configured to implement a digital filter 100. Such digital filter 100 may, for example, include (but is not limited to) de-interleave input logic 101, channel matching logic 102, image rejection logic 103, and absolute calibration logic 104. The de-interleave (channelization) filter 101 partitions the input signal into sub-bands. This is accomplished by low-pass, band-pass, or high-pass filtering the input signal. Each sub-band has a narrower bandwidth than the original signal. Each sub-band shares some frequency content (overlaps) its adjacent bands. Each sub-band is synthesized as an analog waveform in separate signal generation channels.

The channel matching function provided by channel matching logic 102 serves to equalize the magnitude and phase across each of the digital-to-analog and upconversion paths in the system (such as the paths output by y₀, y₁, y₂ and y₃ of DSP 72 in FIGS. 7-9). Such channel matching may be a desirable precursor to removing artifacts, such as signal aliases, in the output signal. Typically, this is implemented as a digital filter. One approach to remove mismatch between the measured frequency responses (H₀, H₁, H₂, H₃) of multiple channels is to calculate the average frequency response (H_{avg}=(H₀+H₁+H₂+H₃)/4), then calculate the channel matching filter that transforms the measured frequency response to the average. For example: the channel matching filter for Channel 0 would be G₀=H_{avg}/H₀.

The image rejection function provided by image rejection logic 103 serves as a hybrid digital/analog filter to cleanly stitch together information in each output channel, although the raw analog signals may have overlapping frequencies.

The absolute calibration step 104 is optional, and may be used to calibrate the signal output power (for example) to an externally referenced level. This step typically requires an external signal reference for calibration purposes.

The digital block (i.e., DSP 72) may also include the functions of removing I/Q mismatch. These mismatches may be created by imbalances between the analog quadrature signals. There may be analog filtering, amplification, or PCB layout related differences between I and Q paths. Pre-correcting the I/Q data before DAC conversion can ensure frequency response mismatches are minimal and return I and Q channels to a 90-degree (orthogonal) relationship.

According to one embodiment, the digital filter 100 is designed using the following procedure:

1.) Measure frequency response function of each channel;

2.) Calculate correction filter (FIR/IIR);

3.) [optional] merge with desired response;

4.) [optional] calculate lower order correction filter; and

5.) [optional] Iterate

In the above procedure, the frequency response function of each channel is first measured. The correction filter (e.g., FIR/IIR) is then calculated. In certain embodiments, the “merge” step combines the correction filter with an optional desired channel response. This optional desired channel response may be a correction to match an external reference power level (for example). The “calculate lower order correction filter” step refers to the fact that oftentimes the algorithm to determine the filter taps for the filters of steps 2 or 3 may yield filters with too many taps. Reducing the filter taps often reduces the cost and complexity of the implementation. Step 4 reduces the number of filter taps by using a lower order approximation to the “ideal” filters calculated previously.

Alternately, in certain embodiments, adaptive filtering is employed within the signal generator, as equalization coefficients may change over time and/or temperature.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method comprising:
receiving, by a wideband signal generator, a plurality of signals; and
frequency interleaving, by the wideband signal generator, the plurality of signals to produce a continuous wideband signal.

2. The method of claim 1 wherein said receiving comprises:
generating said plurality of signals by said wideband signal generator.

3. The method of claim 1 wherein said plurality of signals each have a bandwidth that is less than said continuous wideband signal.

4. The method of claim 1 wherein said frequency interleaving comprises:
overlapping frequencies of said plurality of signals.

5. The method of claim 1 wherein said frequency interleaving comprises:
aligning frequencies of said plurality of signals immediately adjacent each other.

6. The method of claim 1 wherein said frequency interleaving comprises digital signal processing and analog processing of the received plurality of signals.

7. The method of claim 6 wherein said analog processing comprises:
synthesizing the plurality of signals using separate signal generation circuits;
upconverting the plurality of signals to a desired center frequency;
filtering the plurality of signals to remove unwanted spectral components;
employing a frequency reference by the separate signal generation circuits to ensure a fixed frequency and phase relationship between the plurality of signals; and
employing calibration to determine a frequency response of each of the signal generation circuits.

8. The method of claim 6 wherein said digital processing comprises:
filtering an input digital representation of a desired wideband signal to separate the desired wideband signal to multiple narrower band component signals;
filtering each component signal; and
digitally rotating each component signal.

9. The method of claim 8 wherein said filtering each component signal comprises at least one of:
filtering each component signal to compensate for imperfections in a signal generation circuit that generated the component signal;
filtering each component signal to compensate for I/Q modulator imperfections; and
filtering each component signal to compensate for frequency response mismatch between multiple signal generation circuits that are employed for generating the plurality of received signals.

10. The method of claim $ wherein the digitally rotating comprises:
digitally rotating each component signal to compensate for frequency and phase mismatch between multiple signal generation circuits that are employed for generating the plurality of received signals.

11. The method of claim 8 wherein the digital processing further comprises:
applying a nonlinear transformation to compensate for nonlinear imperfections of any analog component used for signal generation or upconversion.

12. A wideband signal generator comprising:
means for receiving a plurality of signals; and
means for frequency interleaving the plurality of signals to produce a continuous wideband signal.

13. The wideband signal generator of claim 12 wherein said means for receiving comprises:
means for generating said plurality of signals.

14. The wideband signal generator of claim 12 wherein said plurality of signals each have a bandwidth that is less than said continuous wideband signal.

15. The wideband signal generator of claim 12 wherein said means for frequency interleaving comprises:
means for overlapping frequencies of said plurality of signals.

16. The wideband signal generator of claim 12 wherein said means for frequency interleaving comprises:
digital processing means; and
analog processing means.

17. The wideband signal generator of claim 12 comprising:
an analog processing block for generating the plurality of signals, said plurality of signals having overlapping frequencies;
a digital processing block for digitally filtering said plurality of signals; and
summation logic for combining the plurality of signals having overlapping frequencies into said continuous wideband signal.

18. A system comprising:
at least three digital-to-analog converters (DACs) each having a sample rate (Fs) for generating a plurality of signals; and
a wideband signal generator for receiving the plurality of signals and frequency interleaving the plurality of signals to form a continuous wideband signal having a bandwidth that is greater than the sample rate (Fs) of the DACs.

19. The system of claim 18 wherein the plurality of DACs comprise M DACs, where M is at least 3. and wherein the continuous wideband signal has a bandwidth W₃ of M*Fs/2.

20. The system of claim 18 wherein the wideband signal generator comprises,
a digital processing block for performing at least one of filtering, phase rotation, frequency translation, and nonlinear corrections; and
an analog processing block for performing at least one of digital-to-analog conversion, image rejection filtering, mixing, upconversion, I/Q modulation, and amplification.
